(19) United States
(12) Patent Application Publication
(10) Pub. No.: US 2025/0135523 A1
(43) Pub. Date: May 1, 2025

(54) THREE LAYERED BUBBLE SHEET COOLING PLATE

(71) Applicant: GM GLOBAL TECHNOLOGY OPERATIONS LLC, Detroit, MI (US)

(72) Inventors: Andrew Clay BOBEL, Troy, MI (US); Diptak BHATTACHARYA, Royal Oak, MI (US); Andrew Geoffrey BALDING, Warren, MI (US); William Yu CHEN, Troy, MI (US); Ryan Curtis SEKOL, Grosse Pointe Woods, MI (US); Derek Frei LAHR, Ann Arbor, MI (US)

(21) Appl. No.: 18/496,602

(22) Filed: Oct. 27, 2023

(51) Int. Cl. B21D 26/021; B21D 19/14; B21D 39/02; B21D 43/22; B21D 53/04

(52) U.S. Cl. CPC B21D 26/021; B21D 19/14; B21D 39/023; B21D 43/22; B21D 39/028; B21D 53/045

(57) ABSTRACT

A method of making a cold plate includes stacking three aluminum sheets on top of each other while each of the three aluminum sheets is generally flat. An edge of the three aluminum sheets are secured together. A top one of the aluminum sheets is welded to a middle one of the aluminum sheets at a plurality of first locations and a bottom one of the aluminum sheets is welded to the middle one of the aluminum sheets at a plurality of second locations different than the plurality of first locations. A pressurized medium is supplied between the top one of the aluminum sheets and the bottom one of the aluminum sheets to separate the top one of the aluminum sheets from the bottom one of the aluminum sheets and deform the middle one of the aluminum sheets.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a three layered bubble sheet cooling plate and a method of making same.

Cold plates are predominantly made using two manufacturing techniques including extrusion and brazing. Cold plates manufactured by extrusion have thick walls with thickness generally greater than 0.4-0.5 mm. Additionally, the extrusion process is limited to the shape and size of the panels. Brazing is a slow and expensive process that requires many fixtures and special manufacturing.

Accordingly it is desirable to provide an alternative method of making a cooling plate with reduced cost and time requirements.

### SUMMARY

According to an aspect of the present disclosure, a method of making a cold plate includes stacking three metal sheets on top of each other while each of the three metal sheets is generally flat. The metal sheeting can include aluminum, copper, steel, steel alloys or other conductive metals and combinations thereof. An edge of the three metal sheets are welded or otherwise secured together. A top one of the metal sheets is bonded to a middle one of the metal sheets at a plurality of first locations and a bottom one of the metal sheets is bonded to the middle one of the metal sheets at a plurality of second locations different than the plurality of first locations. A pressurized medium is supplied between the top one of the metal sheets and the bottom one of the metal sheets to separate the top one of the metal sheets from the bottom one of the metal sheets and deform the middle one of the metal sheets.

According to a further aspect, the middle one of the aluminum sheets can be thinner than both the top one of the aluminum sheets and the bottom one of the aluminum sheets.

According to a further aspect, the pressurized medium is pressurized air.

According to a further aspect, one of the top aluminum sheet and the bottom aluminum sheet includes a coolant inlet port and one of the top aluminum sheet and the bottom aluminum sheet includes a coolant outlet port.

According to a further aspect, the bonding of the top one of the aluminum sheets to the middle one of the aluminum sheets and the bonding of the bottom one of the aluminum sheets to the middle one of the sheets includes one of laser welding, friction welding, resistive welding and roll bonding.

According to a further aspect, the bonding of the edge of the three sheets together includes one of laser welding, friction welding, resistive welding and roll bonding.

According to a further aspect, the bonding the top one of the aluminum sheets to the middle one of the aluminum sheets at a plurality of first locations and the bonding the bottom one of the aluminum sheets to the middle one of the aluminum sheets at a plurality of second locations each include a plurality of line welds.

According to a further aspect, the bonding the top one of the aluminum sheets to the middle one of the aluminum sheets at a plurality of first locations and the bonding the bottom one of the aluminum sheets to the middle one of the aluminum sheets at a plurality of second locations each include a plurality of tack welds.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a cross-sectional view of the cold plate according to the principles of the present disclosure;

FIG. 2a is a schematic cross-sectional view of a stack of aluminum sheets according to the principles of the present disclosure;

FIG. 2b is a schematic cross-sectional view of a plurality of weld location between a stack of aluminum sheets according to the principles of the present disclosure;

FIG. 3 is a schematic plan view of the stack of aluminum sheets showing exemplary weld lines between a top one of the aluminum sheets and a middle one of the aluminum sheets and between a bottom one of the aluminum sheets and the middle one of the aluminum sheets according to the principles of the present disclosure;

FIG. 4 is a schematic plan view of the stack of aluminum sheets showing exemplary circular tack welds between a top one of the aluminum sheets and a middle one of the aluminum sheets and between a bottom one of the aluminum sheets and the middle one of the aluminum sheets according to the principles of the present disclosure;

FIGS. 5a-5c illustrate an expansion of the cold plate from its original stacked and welded condition to an intermediate and final expansion position.

In the drawings, reference numbers may be reused to identify similar and/or identical elements.

### DETAILED DESCRIPTION

With reference to FIG. 1 a three-layered bubble sheet cooling plate 10 according to the principles of the present disclosure is shown. The cooling plate 10 includes a bottom layer aluminum sheet 12, a middle layer aluminum sheet 14 and a top layer aluminum sheet 16. The bottom layer aluminum sheet 12 is connected to the middle layer aluminum sheet 14 by a first plurality of welds 18 and the top layer aluminum sheet 16 is connected to the middle layer aluminum sheet 14 by a second plurality of welds 20 that are offset from the first plurality of welds 18.

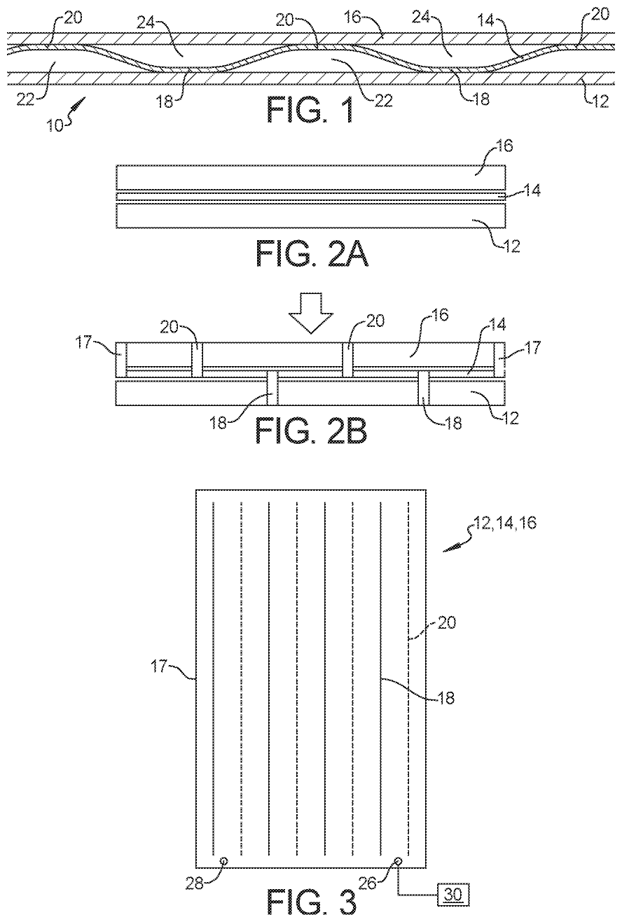

With reference to FIGS. 2a and 2b, a method of making the three-layered bubble sheet cooling plate 10 according to the principles of the present disclosure will now be described. In FIG. 2a, the bottom layer aluminum sheet 12, the middle layer aluminum sheet 14 and the top layer aluminum sheet 16 are stacked on one another while they are all generally flat sheets. The middle aluminum sheet 14 can be thinner and more flexible than the top layer aluminum sheet 16 and the bottom layer aluminum sheet 12. By way of example, the top and bottom aluminum sheets 12, 16 can be 2 to 4 times thicker than the middle aluminum sheet 14. Then, as shown in FIG. 2b, an edge weld 17 or other securing method is provided around a perimeter of the stack aluminum sheets in order to connect the aluminum sheets 12, 14 and 16 together. Then, the bottom layer aluminum sheet 12 is connected to the middle layer aluminum sheet 14 by a plurality of welds 18 and the top aluminum sheet 16 is connected to the middle layer aluminum sheet 14 by a plurality of welds 20.

With reference to FIG. 3, a plan view of the stack of aluminum sheets 12, 14, 16 is shown wherein the solid lines 18 illustrate a plurality of elongated welds 18 between the bottom aluminum sheet 12 and the middle aluminum sheet 14. In addition, the dashed lines 20 illustrate a plurality of elongated welds 20 between the top aluminum sheet 16 and the middle aluminum sheet 14. The elongated welds 18 and 20 can be straight or curvy. The elongated welds 18 and 20 are offset from one another in order to define channels 22, 24 the bottom layer aluminum sheet 12 and the middle layer aluminum sheet 14 and the top layer aluminum sheet 16 and the middle layer aluminum sheet 14, respectively. With reference to FIG. 3, one or both of the bottom layer aluminum sheet 12 and the top layer aluminum sheet 16 can be provided with a coolant inlet port 26 and a coolant outlet port 28.

With reference to FIGS. 5a-5c, an expansion process for expanding the welded together aluminum sheets 12, 14, 16 will now be described. With reference to FIG. 5a, the welded stack of aluminum sheets 12, 14, 16 can be placed in an expandable or fixed dye. A source of pressurized medium 30 such as pressurized air or liquid can be attached to the coolant inlet port and/or the outlet port for delivering the pressurized media into the channels 22, 24 between the stacked aluminum plates. Air can be used for thinner aluminum sheets and water or other liquid can be used for thicker aluminum sheets. With reference to FIG. 5b the structure of the stacked aluminum plates is partially stretched and the dye upper member is moved to an intermediate position and in FIG. 5c, the channels 22, 24 between the stacked aluminum plates are fully formed and the top and bottom sheets reach a desired expanded position. A leak check can be performed during the inflation process.

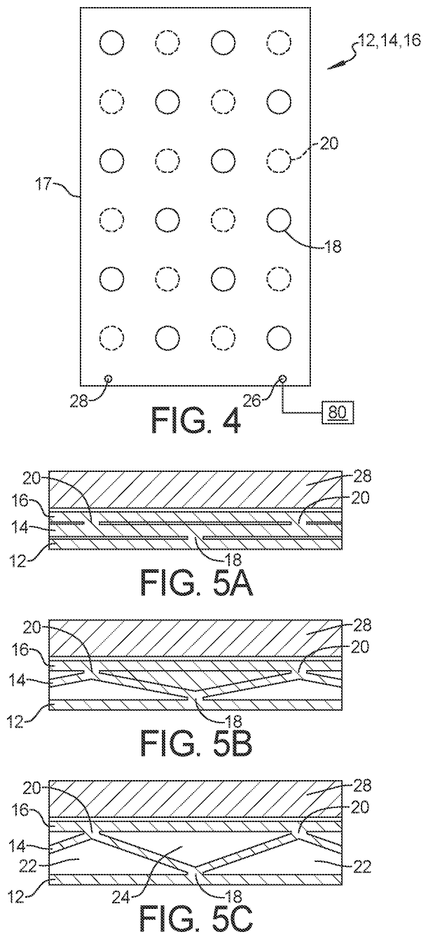

Alternatively, as shown in FIG. 4, a plan view of the stack of aluminum sheets 12, 14, 16 is shown wherein the solid circular lines 18′ illustrate a plurality of spot welds 18′ between the bottom aluminum sheet 12 and the middle aluminum sheet 14. In addition, the dashed circular lines 20′ illustrate a plurality of spot welds 20′ between the top aluminum sheet 16 and the middle aluminum sheet 14. The spot welds 18′ and 20′ are offset from one another in order to define channels the bottom layer aluminum sheet 12 and the middle layer aluminum sheet 14 and the top layer aluminum sheet 16 and the middle layer aluminum sheet 14, respectively. With reference to FIG. 4, one or both of the bottom layer aluminum sheet 12 and the top layer aluminum sheet 16 can be provided with a coolant inlet port 26 and a coolant outlet port 28.

The stack of aluminum sheets 12, 14 and 16 welded together by spot welds 18′, 20′ can then be expanded by introducing a pressurized medium as described above with reference to FIGS. 5a-5c. It should be noted that a combination of spot welds and line welds can also be utilized for forming the three-layered bubble sheet cooling plate 10.

The present disclosure provides a method to manufacture predominantly flat double-sided cold plates 10 using a weld and inflation technique. Three flat aluminum sheets are placed on top of each other. Two out of the three sheets are joined at a time using controlled partial-penetration laser welding or friction welding. Air is passed through the welded stack at a pre-determined pressure based on the sheet thicknesses and the required channel heights to puff up the sheets to create the channeled structure. The middle sheet deforms leaving the two outer sheets flat or generally flat for interfacing with the battery walls. The cold plate requires low-cost simple tooling compared to prior cold plate designs. The process avoids stamping operations and tooling that is typically required for braising. Multiple joining methods are available including laser welding, friction welding or a roll bonding process can be used with appropriate mask sheeting used to prevent bonding in the masked areas. The coolant channel's mixed regions via partial channel welding can reduce risk of coolant vaporization during a cell thermal event. The simple process of formation utilizing 3 flat aluminum sheets without requiring trimming or pre shaping provides a reduction in prototype and production costs and times.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A method of making a cold plate, comprising:
stacking three metal sheets on top of each other while each of the three metal sheets is generally flat;
securing an edge of the three metal sheets together;
bonding a top one of the metal sheets to a middle one of the metal sheets at a plurality of first locations;
bonding a bottom one of the metal sheets to the middle one of the metal sheets at a plurality of second locations different than the plurality of first locations;
supplying a pressurized medium between the top one of the metal sheets and the bottom one of the metal sheets to separate the top one of the metal sheets from the bottom one of the metal sheets and deform the middle one of the metal sheets.

2. The method according to claim 1, wherein the middle one of the metal sheets is thinner than both the top one of the metal sheets and the bottom one of the metal sheets.

3. The method according to claim 1, wherein the pressurized medium is pressurized air.

4. The method according to claim 1, wherein one of the top metal sheet and the bottom metal sheet includes a coolant inlet port and one of the top metal sheet and the bottom metal sheet includes a coolant outlet port.

5. The method according to claim 1, wherein the bonding of the top one of the metal sheets to the middle one of the metal sheets and the bonding of the bottom one of the metal sheets to the middle one of the sheets includes one of laser welding, friction welding, resistance welding and roll bonding.

6. The method according to claim 1, wherein the securing the edge of the three metal sheets together includes one of laser welding, friction welding, resistance welding and roll bonding.

7. The method according to claim 1, wherein the bonding the top one of the metal sheets to the middle one of the metal sheets at a plurality of first locations and the bonding the bottom one of the metal sheets to the middle one of the metal sheets at a plurality of second locations each include a plurality of line welds.

8. The method according to claim 1, wherein the bonding the top one of the metal sheets to the middle one of the metal sheets at a plurality of first locations and the bonding the bottom one of the metal sheets to the middle one of the metal sheets at a plurality of second locations each include a plurality of tack welds.

9. A method of making a cold plate, comprising:
stacking three aluminum sheets on top of each other while each of the three aluminum sheets is generally flat, wherein a middle one of the aluminum sheets is thinner than both a top one of the aluminum sheets and a bottom one of the aluminum sheets;
bonding an edge of the three aluminum sheets together;
bonding the top one of the aluminum sheets to the middle one of the aluminum sheets at a plurality of first locations;
bonding the bottom one of the aluminum sheets to the middle one of the aluminum sheets at a plurality of second locations different than the plurality of first locations;
supplying a pressurized medium between the top one of the aluminum sheets and the bottom one of the aluminum sheets to separate the top one of the aluminum sheets from the bottom one of the aluminum sheets and deform the middle one of the aluminum sheets.

10. The method according to claim 9, wherein the pressurized medium is pressurized air.

11. The method according to claim 9, wherein the pressurized medium is a liquid.

12. The method according to claim 9, wherein the bonding of the top one of the aluminum sheets to the middle one of the aluminum sheets and the bonding of the bottom one of the aluminum sheets to the middle one of the sheets includes one of laser welding, friction welding, resistance welding and roll bonding.

13. The method according to claim 9, wherein the bonding of the edge of the three sheets together includes one of laser welding, friction welding, resistance welding and roll bonding.

14. The method according to claim 9, wherein the bonding the top one of the aluminum sheets to the middle one of the aluminum sheets at a plurality of first locations and the welding the bottom one of the aluminum sheets to the middle one of the aluminum sheets at a plurality of second locations each include a plurality of line welds.

15. The method according to claim 9, wherein the bonding the top one of the aluminum sheets to the middle one of the aluminum sheets at a plurality of first locations and the bonding the bottom one of the aluminum sheets to the middle one of the aluminum sheets at a plurality of second locations each include a plurality of tack welds.

16. The method according to claim 9, wherein one of the top aluminum sheet and the bottom aluminum sheet includes a coolant inlet port and one of the top aluminum sheet and the bottom aluminum sheet includes a coolant outlet port.

17. A battery module cooling plate, comprising:
a bottom metal sheet;
a middle metal sheet bonded to the bottom metal sheet along an edge of the middle metal sheet and the bottom metal sheet and at a plurality of first intermediate locations, the middle metal sheet further bonded to a top metal sheet along an edge of the middle metal sheet and the top metal sheet and at a plurality of second intermediate locations different than the first intermediate locations, wherein the top metal sheet and the bottom metal sheet are spaced from one another and the middle metal sheet is undulating between the top metal sheet and the bottom metal sheet.

18. The battery module cooling plate according to claim 17, wherein the middle metal sheet is bonded to the top metal sheet by a plurality of first welds and the middle metal sheet is bonded to the bottom metal sheet by a plurality of second welds.

19. The battery module cooling plate according to claim 17 wherein the middle metal sheet is bonded to the top metal sheet and the middle metal sheet is bonded to the bottom metal sheet by at least one of a laser weld, a friction weld, a resistance weld and roll bonding.

20. The battery module cooling plate according to claim 17, wherein the middle metal sheet is thinner than the top metal sheet and the bottom metal sheet.
